(19) United States
(12) Patent Application Publication
(10) Pub. No.: US 2025/0113516 A1
(43) Pub. Date: Apr. 3, 2025

(54) CONTROLLED RECESS OF DUMMY GATE TO TARGET ACTIVE TRANSISTOR PORTION

(71) Applicant: Intel Corporation, Santa Clara, CA (US)

(72) Inventors: Kiran Chikkadi, Hillsboro, OR (US); Michael L. Hattendorf, Portland, OR (US); Darshil Gala, Milpitas, CA (US); Maheshwar Ghimire, Hillsboro, OR (US); Ryan Wood, Beaverton, OR (US)

(73) Assignee: Intel Corporation, Santa Clara, CA (US)

(21) Appl. No.: 18/375,287

(22) Filed: Sep. 29, 2023

(51) Int. Cl. H01L 29/66; H01L 21/8234; H01L 27/088; H01L 29/06; H01L 29/78

(52) U.S. Cl. CPC H10D 30/024; H10D 30/62; H10D 62/115; H10D 62/118; H10D 64/015; H10D 64/017; H10D 84/0135; H10D 84/0147; H10D 84/0149; H10D 84/0151; H10D 84/0158; H10D 84/038; H10D 84/83

(57) ABSTRACT

An integrated circuit (IC) device includes a transistor channel region within (and over a base of) a semiconductor fin, a gate structure over the fin, an isolation or dielectric material adjacent the base of the fin, and an intervening spacer material adjacent the fin, over the dielectric material, and between the channel region (and gate structure) and the isolation or dielectric material. The intervening spacer material may be at substantially equal heights on both sides of the fin. The intervening spacer material may have a height or thickness that is substantial portion of the height of the fin. The spacer and isolation materials may be on both sides of the fin, and between the fin and adjacent fins.

### BACKGROUND

Modern transistors are typically designed to achieve both high performance and high power efficiency. Power efficiency is critical for key applications, e.g., both in mobile computing and data center applications. Power efficiency of the chip heavily depends on source-to-drain leakage current of a transistor while the transistor is nominally off. Reducing this leakage without compromising on the on-state current of the transistor improves product performance but is increasingly difficult as transistor structures and pitches are shrunk.

New structures and techniques are needed to improve device performance and efficiency while continually scaling transistors.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A and 1B illustrates a cross-sectional profile view of devices with transistors having a channel region in a fin and a spacer material separating the channel region and an adjacent gate structure from a bulge in the fin, in accordance with some embodiments;

FIGS. 2A and 2B illustrate cross-sectional profile and plan views of a device with multiple transistors having gate structures over channel regions in one or more fins, in accordance with some embodiments;

FIG. 3 illustrates a cross-sectional profile view of a transistor and multiple fins, including various key structural dimensions, such as heights and widths, in accordance with some embodiments;

FIG. 4 is a flow chart of methods for forming a transistor with a spacer between a channel region and wider base of a fin, including removing a portion of a dummy material and retaining a portion as the spacer, in accordance with some embodiments;

FIGS. 5A, 5B, 5C, 5D, 5E, 5F, 5G, 5H, 5I, 5J, 5K, 5L, 5M, and 5N illustrate cross-sectional profile views of fins and transistors, at various stages of manufacture, in accordance with some embodiments;

FIG. 6 illustrates a diagram of an example data server machine employing a device with transistors having spacers between gate structures and isolation materials between fins, in accordance with some embodiments; and

FIG. 7 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected.” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve the performance of integrated circuit (IC) devices having FinFETs, field-effect transistors (FETs) with channels in fins of semiconductor material. FinFET conduction depends heavily on the size and shape of the fins, and the corresponding channel regions, that make up the FinFETs. The formation and other processing of these fins (e.g. by etching away materials from a substrate) often results in unwanted kinks or bulges in the fins, for example, due to the non-zero selectivity of these etches, which may inadvertently remove portions of (and so thin) the fins along with the material(s) to be removed. For example, an etch meant to remove a silicon dioxide isolation material over and between silicon fins may also remove small (but potentially significant) amounts of semiconducting silicon from the fins. Such fin thinning may leave bulges with uncontrolled variability below the thinned portions. These non-uniformities may result in uncontrolled conduction, for example, subthreshold conduction, such as leakage current, when the transistor should be, and nominally is, off. This description discloses structures and processes for reducing these leakage currents.

The electrical height of the transistor, e.g., the channel region of a FinFET, may be defined by recessing an isolation material (e.g., an oxide) around the fin. Unwanted kinks or bulges may result at and below an interface of the retained isolation material, where the fins are thicker or wider below the thinned tops of the fins. Device performance can be improved, and leakage currents may be reduced, by more precisely defining FinFET channel regions, for example, to not include unwanted thicker portions of the fins.

A spacer material may be formed over the isolation material around and between fins to provide separation between the defined channel regions and the undesired geometries in the fins. In some embodiments, a well-understood and -controlled material, such as those used for dummy gates in many standard processes, is used as the spacer material. A well-controlled and highly selective etch of a dummy gate may be used to remove most of the sacrificial dummy gate, but to also retain a precise portion of the dummy material. This retained dummy material may act as a spacer between a subsequently-formed gate structure (over the channel region) and a non-uniformity of the fin at an interface with the isolation material. In some embodiments, a polysilicon dummy-gate material is employed as the spacer material. In some embodiments, the spacer material is over a silicon oxide (e.g., silicon dioxide (SiO₂) isolation material. In some embodiments, the spacer material is adjacent one or more fins of silicon.

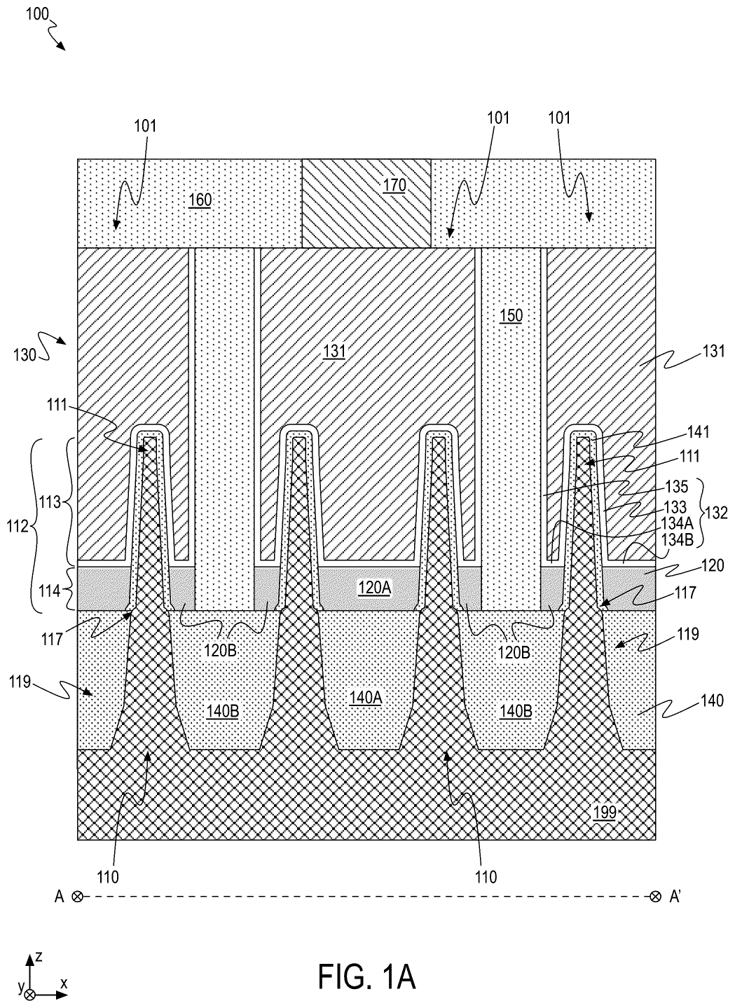

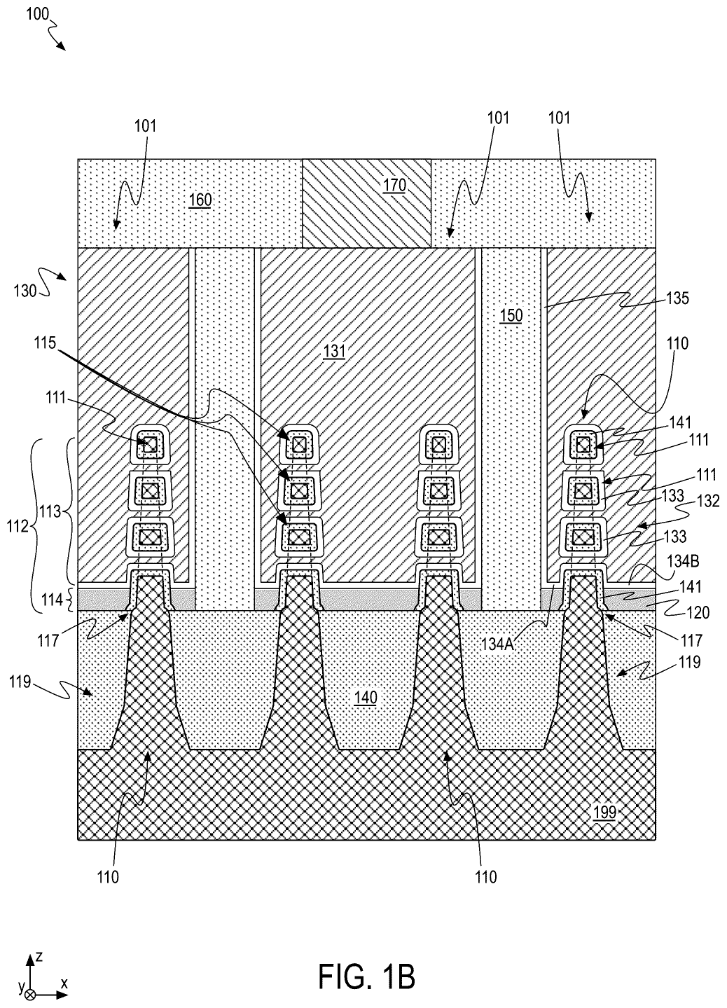

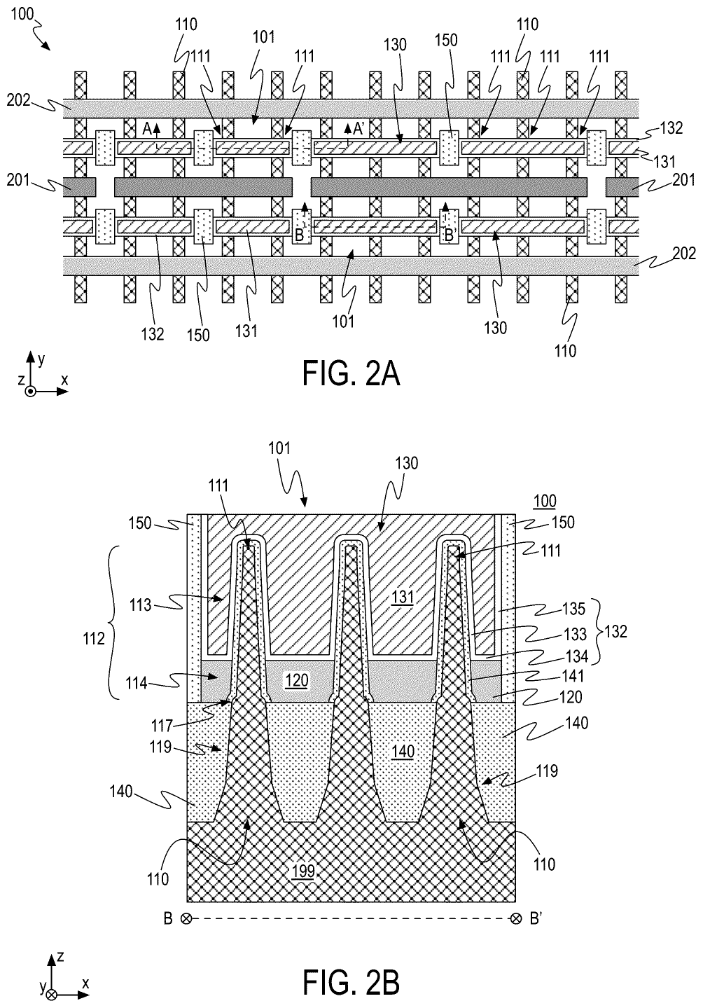

FIGS. 1A and 1B illustrate cross-sectional profile views of devices 100 with transistors 101 having a channel region 111 in a fin 110 and a spacer material 120 separating channel region 111 and adjacent gate structure 130 from a bulge 117 in fin 110, in accordance with some embodiments. FIG. 1A shows IC device 100 having multiple fins 110 of silicon (or another semiconductor material) over substrate 199, e.g., of the same semiconductor material. Each fin 110 includes a base 119 and an upper portion 112 over base 119. Spacer material 120 is adjacent, and on both sides of, middle portions 114 of fins 110. An isolation material 140 is between fins 110, adjacent base 119. Spacer material 120 is between fins 110 and over isolation material 140. Cross-sectional line A-A′ indicates how the cross-sectional profile viewing plane of FIG. 1A is orientated in the plan view of FIG. 2A.

IC device 100 includes multiple transistors 101 with a channel region 111 within at least one fin 110. Each fin 110 includes a channel region 111 within upper portion 112 and over base 119. Base 119 is under channel region 111 and top and middle portions 113, 114. Transistor 101 includes a gate structure 130 over fins 110, adjacent channel region 111. Spacers 150 are between adjacent transistors 101, e.g., between adjacent gate structures 130. Gate structure 130 includes a gate metal 131 and a gate insulator 132. Gate insulator 132 may be conformally over and on adjacent structures. Portions 133 of gate insulator 132 are over fin 110 and between gate metal 131 and channel regions 111. Portions 134 (e.g., portions 134A, 134B) of insulator 132 are between gate metal 131 and an intervening, spacer material 120, including between adjacent fins 110. Portions 134A, 134B are over spacer material 120 to both sides of each fin 110. Gate insulator 132 (e.g., portions 135 of insulator 132) may be conformally over adjacent spacers 150. Spacer material 120 is between gate structure 130 and isolation material 140.

Intervening material 120 is adjacent fins 110 and over dielectric material 140. Intervening material 120 is between adjacent fins 110. Fins 110 are between adjacent regions of intervening material 120 (e.g., a region of intervening material 120A and a region of intervening material 120B), such that intervening material 120A, 120B is on both sides of each fin 110. Intervening material 120 is adjacent fin 110 at a middle portion 114 of fin 110. Middle portion 114 is in upper portion 112 of fin 110, but below a top portion 113 of upper portion 112 and fin 110. Middle portion 114 is between top portion 113 and base 119. Gate structure 130 (including metal 131 and insulator 132) is adjacent fin 110 at top portion 113 of fin 110. Gate structure 130 is over regions of spacer material 120 on both sides of each fin 110. Regions or sections of isolation material 140 are under regions of spacer material 120. Regions of isolation material 140 are adjacent fin 110 at base 119, which is under the middle portion 114 adjacent regions of spacer material 120. Fins 110 are between adjacent regions of isolation material 140 (e.g., a region of isolation material 140A and a region of isolation material 140B), and isolation material 140A, 140B is on both sides of each fin 110.

Intervening spacer material 120, between gate structure 130 and isolation material 140, provides separation between channel region 111 (adjacent gate structure 130) and kink or bulge 117 of fin 110. Sufficient distance between bulge 117 and channel region 111 (e.g., between gate structure 130 and isolation material 140) may improve control of the conduction of channel regions 111 and transistors 101. Such improved control may reduce leakage currents resulting from bulge 117. Spacer material 120 may be any suitable material. Spacer material 120 may be retained dummy material, for example, as used in a dummy gate process. In many embodiments, spacer material 120 is or includes silicon. In some such embodiments, spacer material 120 is polycrystalline silicon.

Isolation material 140 may be a dielectric material, e.g. a low-permittivity (“low-K”) dielectric material, that electrically isolates or insulates adjacent fins. Isolation material 140 may be in trenches, e.g., as shallow trench isolation (STI), between fins. Isolation material 140 may be any suitable material. In many embodiments, isolation material 140 includes oxygen. Isolation material 140 may be or include an oxide of silicon, such as silicon dioxide (e.g., SiO₂).

In some embodiments, a layer 141 of dielectric material 140 is between middle portion 114 of fin 110 and the regions of spacer material 120 on both sides of fin 110. In some such embodiments, layer 141 is over fin 110, between channel region 111 and portion 133 of gate insulator 132. The layer 141 is connected (e.g., directly coupled) to the regions of dielectric material 140 adjacent base 119 and on both sides of fin 110. In some embodiments, layer 141 is of dielectric material 140. In other embodiments, layer 141 includes a different dielectric material. A thin layer 141, if present, may advantageously provide insulation between spacer material 120 and fin 110. A thin layer 141, if present, may advantageously provide a protective layer (e.g., as a passivation layer) for fin 110.

A spacer 150 may provide isolation between adjacent transistors 101, for example, between adjacent gate structures 130. Spacer 150 may be any suitably electrically insulative material, such as a low-K dielectric material. In many embodiments, spacer 150 includes nitrogen and/or oxygen. In some embodiments, spacer 150 includes silicon, nitrogen, and oxygen (such as in a silicon oxynitride). Other materials may be employed. In many embodiments, an etch selectivity exists between isolation material 140 and the material of spacer 150, which may provide (e.g., processing) advantages during manufacture.

Inter-layer isolation 160 may also be a low-K dielectric material (such as an inter-layer dielectric (ILD)) or other suitable electrical isolation. Isolation 160 electrically insulates transistors 101 from structures, e.g., electrical interconnects, in layers above transistors 101.

Electrical interconnects in layers above transistors 101 are coupled to transistors 101, e.g., gate metal 131 of gate structures 130, by contacts 170, which may be of any sufficiently electrically conductive material(s), such as one or more metals. Similar contacts (not shown) may electrically couple source and drain terminals (not shown) of transistors 101, e.g., in front of and behind the viewing plane of FIG. 1A (e.g., in the y direction).

Such source and drain terminals may be impurity-doped semiconductor that is electrically and physically coupled to opposite sides of channel regions 111. Such doped semiconductor may include faceted epitaxial material that has been grown from one or both ends of channel regions 111 within gate structures 130, and/or from source/drain ends of fins 110, and/or from substrate 199, etc. Doped semiconductor need not be epitaxial material. In some embodiments, doped semiconductor is a Group IV semiconductor material (e.g., Si, Ge, SiGe or GeSn alloy). Other semiconductor materials may be used. Impurity-doped semiconductor may include one or more electrically active impurities. Doped semiconductor may include an n-type impurity (such as phosphorus, arsenic, or antimony) or a p-type impurity (such as boron or aluminum).

Substrate 199 and fins 110 may be silicon or of other materials. Substrate 199 may include any suitable material or materials. Any suitable semiconductor or other material can be used. Substrate 199 may be any suitable substrate, such as a wafer, die, etc. Substrate 199 may include a semiconductor material that transistors can be formed out of or on, including a crystalline material, such as monocrystalline or polycrystalline silicon (Si), germanium (Ge), silicon germanium (SiGe), a III-V alloy material (e.g., gallium arsenide (GaAs)), a silicon carbide (SiC), a sapphire (Al₂O₃), or any combination thereof. In some embodiments, substrate 199 includes crystalline silicon and subsequent components are also silicon. In some embodiments, substrate 199 is a silicon-on-insulator (SOI) substrate. One or multiple fins 110 of semiconductor material may be included in or on substrate 199. Fins 110 may be of the same material as substrate 199 or formed, e.g., deposited, on substrate 199. Substrate 199 may also include semiconductor materials, metals, dielectrics, dopants, and other materials commonly found in IC substrates.

FIG. 1B illustrates another IC device 100 having multiple fins 110 of a semiconductor material over substrate 199. Notably, in the example of FIG. 1B, fins 110 include nanoribbons 115 in top portions 112, and transistors 101 include channel regions 111 in nanoribbons 115 over base 119. Nanoribbons 115 may be separated from other nanoribbons 115 and from base 119 by gaps in fins 110. As described in the example of FIG. 1A, intervening spacer material 120 provides separation between channel region 111 (adjacent gate structure 130) and kink or bulge 117. Sufficient distance between bulge 117 and channel region 111 may improve control of the conduction of channel regions 111 and transistors 101, for example, by enabling the formation of substantially uniform channel regions 111 in fins 110 fabricated with minimal process variation. Such improved control may reduce leakage currents resulting from bulge 117.

Each fin 110 includes a base 119 and an upper portion 112 over base 119. Upper portion 112 includes top and middle portions 113, 114 of fin 110. Top portion 113 of fin 110 includes multiple nanoribbons 115 separated by gaps in top portion 113. (Nanoribbons 115 may be characterized as nanowires or nanosheets, for example, in narrower or wider fins 110.) Nanoribbons 115 each include a channel region 111 (or a single channel region 111 of each fin 110 can be considered to include each of the multiple nanoribbons 115). The outlines of sidewalls of fin 110 at gaps in top portion 113 and between nanoribbons 115 are shown as dashed. Source and drain terminals may be impurity-doped semiconductor electrically and physically coupled to opposite ends of nanoribbons 115 and channel regions 111. Such doped semiconductor may include faceted epitaxial material that has been grown from each end of nanoribbons 115 and merged to provide a terminal common to nanoribbons 115 in a stack of nanoribbons 115. Spacer material 120 is adjacent, and on both sides of, middle portions 114 of fins 110. An isolation material 140 is between fins 110, adjacent base 119. Spacer material 120 is between fins 110 and over isolation material 140.

IC device 100 includes multiple transistors 101 with channel regions 111 in nanoribbons 115 in upper portion 112 of fins 110. Each fin 110 includes channel regions 111 within upper portion 112 and over base 119. Base 119 is under channel regions 111 in nanoribbons 115. Transistor 101 includes a gate structure 130 over nanoribbons 115 in fins 110, adjacent channel region 111. Gate structure 130 includes a gate metal 131 and a gate insulator 132. Gate insulator 132 may be conformally over and on adjacent structures. Portions 133 of gate insulator 132 are over and conformally around nanoribbons 115 of fin 110 and between gate metal 131 and channel regions 111. In some embodiments, a layer 141 of dielectric material 140 is between (portions 133 of) gate insulator 132 and channel regions 111 (in nanoribbons 115). Portions 134 (e.g., portions 134A, 134B) of insulator 132 are between gate metal 131 and an intervening, spacer material 120, including between adjacent fins 110. Portions 134A, 134B are over spacer material 120 to both sides of each fin 110. Gate insulator 132 (e.g., portions 135 of insulator 132) may be conformally over adjacent spacers 150. Spacer material 120 is between gate structure 130 and isolation material 140.

Intervening material 120 is adjacent fins 110 and over dielectric material 140. Intervening material 120 is between adjacent fins 110. Fins 110 are between adjacent regions of intervening material 120 (e.g., a region of intervening material 120A and a region of intervening material 120B), such that intervening material 120A, 120B is on both sides of each fin 110. Intervening material 120 is adjacent fin 110 at a middle portion 114 of fin 110. Middle portion 114 is in upper portion 112 of fin 110, but below a top portion 113 of upper portion 112 and fin 110. Middle portion 114 is between top portion 113 and base 119. Gate structure 130 (including metal 131 and insulator 132) is adjacent fin 110 (including nanoribbons 115 in fins 110) at top portion 113. Gate structure 130 is over regions of spacer material 120 on both sides of each fin 110. Regions or sections of isolation material 140 are under regions of spacer material 120. Regions of isolation material 140 are adjacent fin 110 at base 119, which is under the middle portion 114 adjacent regions of spacer material 120. Fins 110 are between adjacent regions of isolation material 140 (e.g., a region of isolation material 140A and a region of isolation material 140B), and isolation material 140A, 140B is on both sides of each fin 110.

FIGS. 2A and 2B illustrate cross-sectional profile and plan views of device 100 with multiple transistors 101 having gate structure 130 over channel regions 111 in one or more fins 110, in accordance with some embodiments. Plan view of FIG. 2A shows an exemplary layout of at least part of an array of multiple adjacent transistors 101, e.g., with gate structures 130 separated by spacers 150. Some materials and structures are, for clarity and/or illustration purposes, not shown. Cross-sectional lines A-A′ and B-B′ show the orientation (in the plan view of FIG. 2A) of the cross-sectional profile viewing planes of FIGS. 1 and 2B. The cross-sectional view of FIG. 1A at line A-A′ shows two fins 110 and a transistor 101 between spacers 150 and other fins 110 and transistors 101. The cross-sectional view of FIG. 2B at line B-B′ shows three fins 110 in a transistor 101 between spacers 150 (separating transistor 101 from other fins 110 and transistors 101). Other transistors 101 may have more or fewer channel regions 111 in more or fewer fins 110.

Drain and source contacts 201, 202 may be similar to gate contacts 170 (not shown). Contacts 201, 202 may electrically couple transistors 101 (e.g., at drain and source ends of channel regions 111 within fins 110) to electrical interconnect layers above transistors 101. For example, source contacts 202 may be coupled to a voltage supply Vss (not shown), and drain contacts 201 may be coupled to other drain contacts 201 (e.g., in an inverter connection) and/or an output terminal of a circuit (such as an inverter or other gate). In some embodiments, some contacts 202 shown in FIG. 2A (e.g., on both sides, in the y direction, of drain contacts 201) are in electrical parallel such that some transistors 101 (e.g., transistors 101 aligned in the y direction) are in electrical parallel (e.g., parallel legs of a larger transistor). Transistors 101 may be coupled in other configurations.

Contacts 201, 202 may electrically couple to drain and source terminals, e.g., of impurity-doped semiconductor, such as faceted epitaxial material (as described at FIG. 1A). Contacts 201, 202 may be of any sufficiently electrically conductive material(s), such as one or more metals.

Gate structures 130 are over corresponding fins 110 and channel regions 111. Gate structures 130 include gate metal 131 encircled by gate insulator 132. Gate insulator 132 may be a layer conformal to adjacent structures (not shown), such as spacers between adjacent terminals or contacts of transistors 101.

Spacers 150 are between adjacent gate structures 130 and corresponding fins 110. The same or a similar spacer or isolation material may be (not shown), for example, between and over fins 110 and separating gate structures 130 from adjacent source and drain contacts 201, 202. In many embodiments, an etch selectivity exists between the material of spacers 150 and a material of any spacers between gate structures 130 and adjacent source and drain contacts 201, 202. Such an etch selectivity may provide (e.g., processing) advantages during manufacture.

FIG. 2B illustrates cross-sectional profile view of transistor 101 and multiple fins 110 at cross-sectional line B-B′ shown in the plan view of FIG. 2A. FIG. 2B shows a similar view as that shown at FIG. 1A. Notably, transistor 101 in FIG. 2B includes three channel regions 111 in corresponding fins 110 between spacer 150, which separate gate structure 130 and transistor 101 from adjacent gate structures 130 and transistors 101.

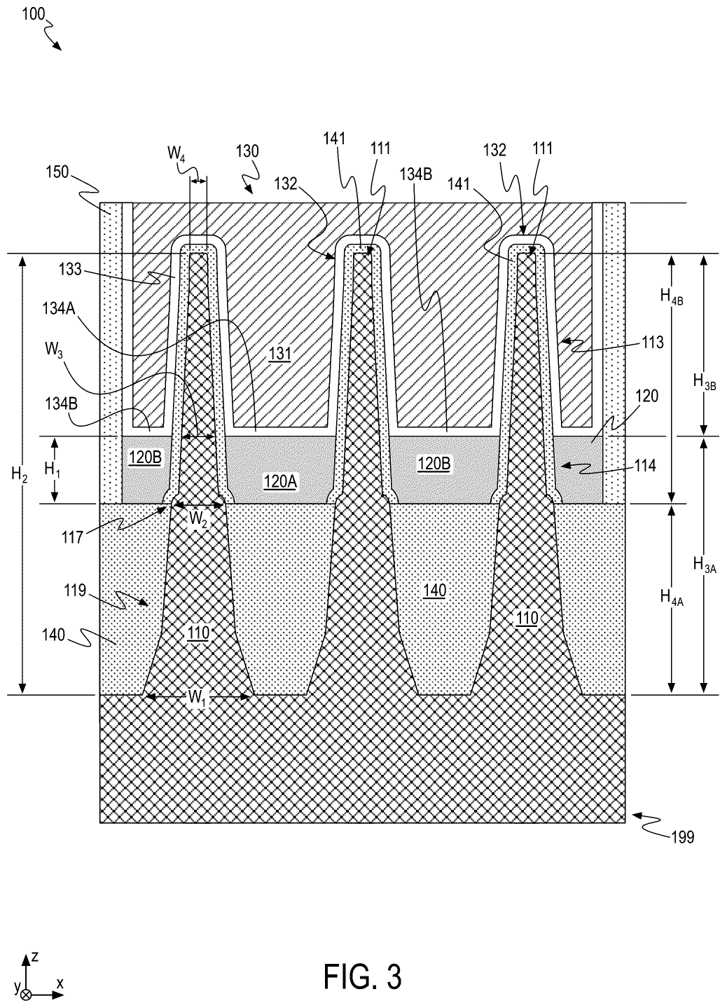

FIG. 3 illustrates a cross-sectional profile view of transistor 101 and multiple fins 110, including various key structural dimensions, such as heights and widths, in accordance with some embodiments. Such dimensions, as described at least here at FIG. 3 below, may be critical for optimizing and properly controlling the conduction of channel regions 111 and transistor 101. For example, consistent control of conduction through channel regions 111 may be optimized in narrow fins 110 with consistent widths (e.g., widths W₃, W₄) along channel regions 111. In some embodiments, widths W₃, W₄ for a given fin 110 are advantageously substantially equal (e.g., along a height H_{3B} of channel region 111 and top portion 113 of fin 110). In some embodiments, widths W₃ and/or W₄ are advantageously substantially equal (e.g., along height H_{3B}) for multiple fins 110 (e.g., within a same transistor 101 or in adjacent transistors 101). In some embodiments, a short height H_{3B} (or consistent heights H_{3B} of multiple top portions 113 and channel regions 111 for multiple fins 110) may advantageously correspond to good or consistent control of conduction through channel regions 111. In some embodiments, a tall height H_{3B} may correspond to advantageous (e.g., more) conduction through channel regions 111.

In some embodiments, consistent (or otherwise advantageous) control of conduction through channel regions 111 may be improved by having substantially symmetric gate structures 130 immediately adjacent to fins 110. In some such embodiments, portion 134A of gate insulator 132 connects to (e.g., a first side of) portion 133 (e.g. over a given fin 110) of insulator 132 at a first height (e.g., height H_{3A}), and the portion 134B of insulator 132 connects to (e.g., a second, opposite side of) portion 133 (e.g. over the same fin 110) at a second height (e.g., also height H_{3A}) substantially equal to the first height. Heights H_{3A} are referenced downward to a bottom of fins 110, at substrate 199, but the heights of the same connections of portions 134 (e.g., portions 134A, 134B) may be referenced upward (e.g., to top edges of fins 110) by heights H_{3B}. Portions 134 are advantageously substantially level between fins 110 and connect to portions 133 at substantially the same heights H_{3A}, H_{3B}, which may be enabled by an isotropic and highly selective etch of spacer material 120 during manufacture.

Optimized control of the conduction of channel regions 111 and transistor 101 may be achieved by providing (e.g., vertical) separation between channel regions 111 (in top portions 113) and bulges 117 of fins 110, where a width (e.g., width W₂) of fin 110 may be uncontrollably wider (e.g., than widths W₃, W₄). In some embodiments, width W₂ (e.g., taken at the height H_{4A} or H_{4B}, at an interface of materials 120, 140) is more than 20% greater than width W₃ (e.g., taken at the height H_{3A} or H_{3B}, at an interface of spacer material 120 and portion 134 of insulator 132). In some embodiments, width W₂ is more than 50% greater than width W₄ (e.g., taken at the height H₂, at a top edge of fin 110).

In some embodiments, a height (e.g., height H₁) of middle portion 114 of fin 110, between top portion 113 and base 119, and adjacent intervening spacer material 120, is less than a tenth of a height (e.g., height H₂) of fin 110 (e.g., from substrate 199 to a top edge of fin 110). Height H₁ being such a short portion of the height H₂ of fin 110 may maximize a height H_{3B} of channel regions 111 and top portions 113 of fin 110. Height H₁ of middle portion 114 of fin 110 is also a height H₁ or thickness of spacer material 120 adjacent middle portion 114. In some embodiments, height H₁ of middle portion 114 is equal to or greater than half of height H₂ of fin 110. Height H₁ being such a tall portion of the height H₂ of fin 110 may ensure sufficient separation between channel regions 111 (in top portions 113) and bulges 117 of fins 110. In some embodiments, height H₁ of middle portion 114 is a quarter, or a third, or between a quarter and a third of, height H₂ of fin 110. Such a height H₁ may be an optimized portion of the height H₂ that has adequate separation between channel regions 111 (in top portions 113) and bulges 117 of fins 110, but also enables sufficient conduction of channel regions 111 and transistor 101 (e.g., by providing sufficient height H_{3B} of channel regions 111 and top portions 113).

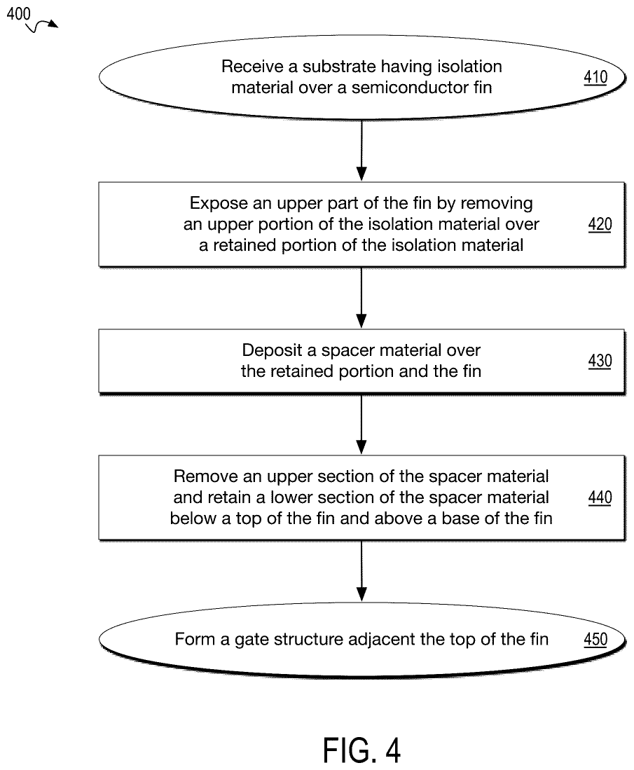

FIG. 4 is a flow chart of methods 400 for forming a transistor with a spacer between a channel region and wider base of a fin, including removing a portion of a dummy material and retaining a portion as the spacer, in accordance with some embodiments. Methods 400 include operations 410-450. Some operations shown in FIG. 4 are optional. Additional operations may be included. FIG. 4 shows an example sequence, but the operations can be done in other orders as well, and some operations may be omitted. Some operations can also be performed multiple times before other operations are performed. For example, multiple transistors may be formed or multiple spacers may be formed adjacent one or multiple fins. Some operations may be included within other operations so that the number of operations illustrated FIG. 4 is not a limitation of the methods 400.

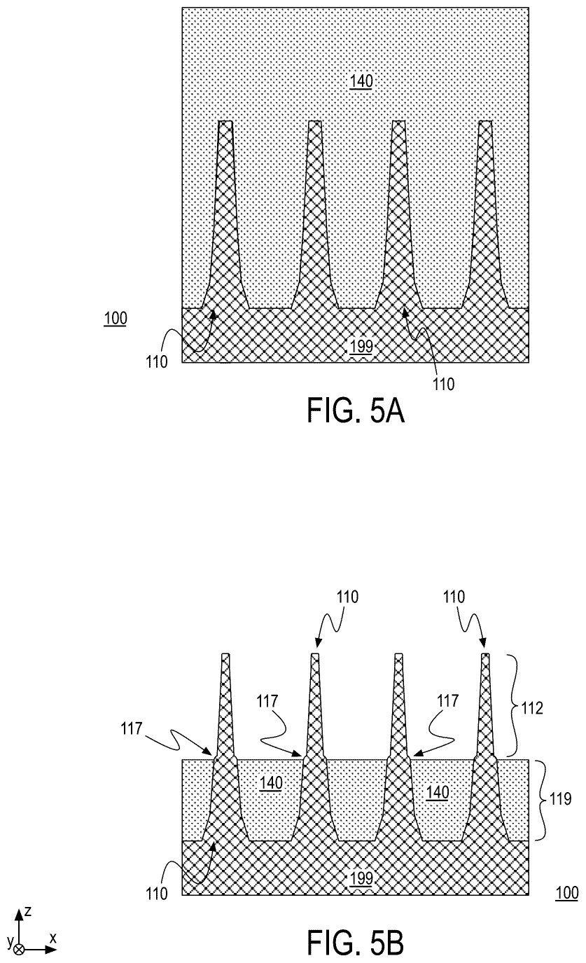

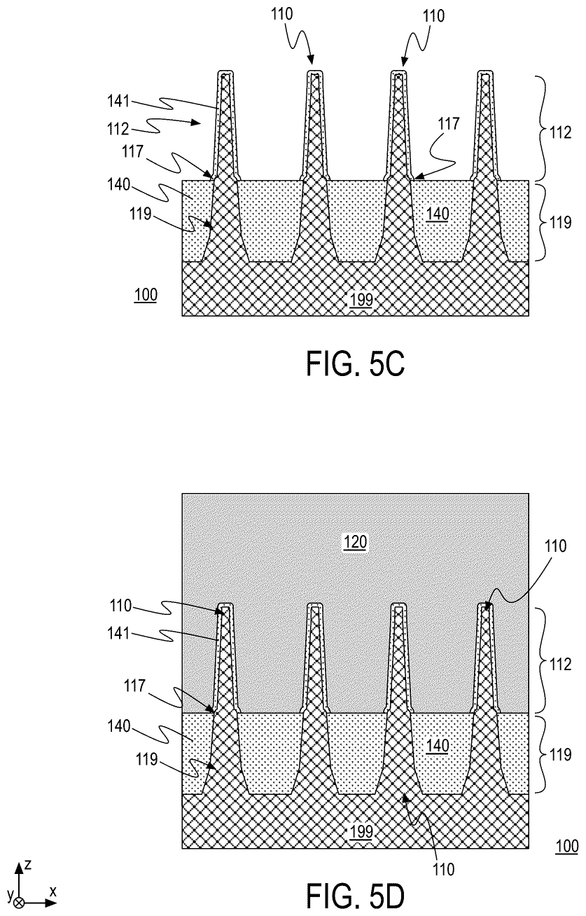

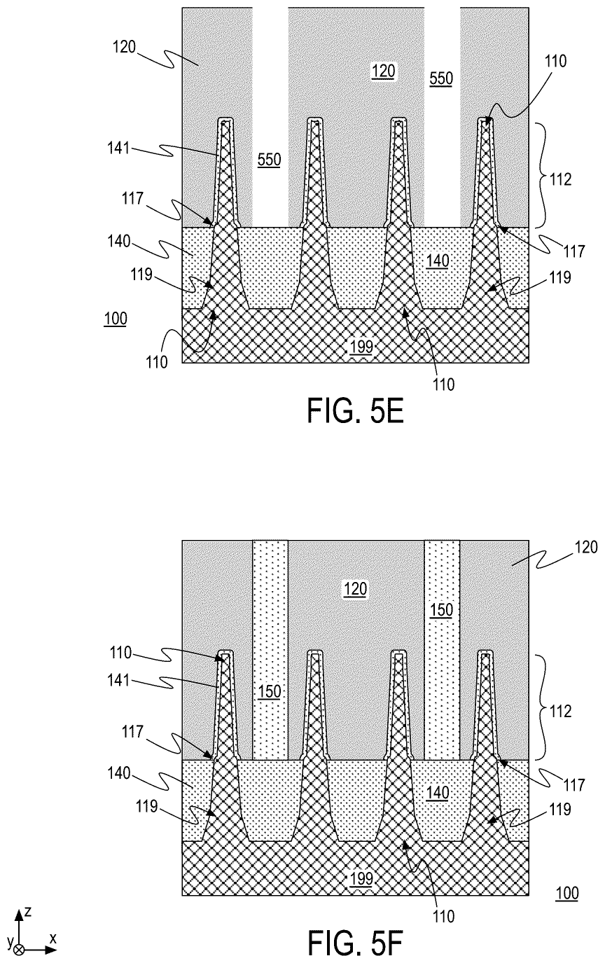

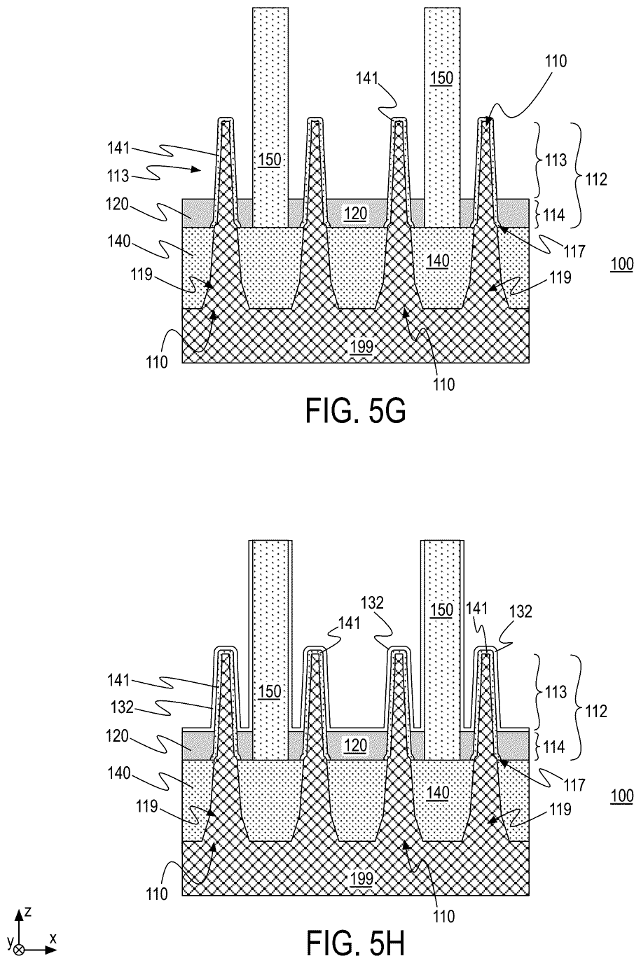

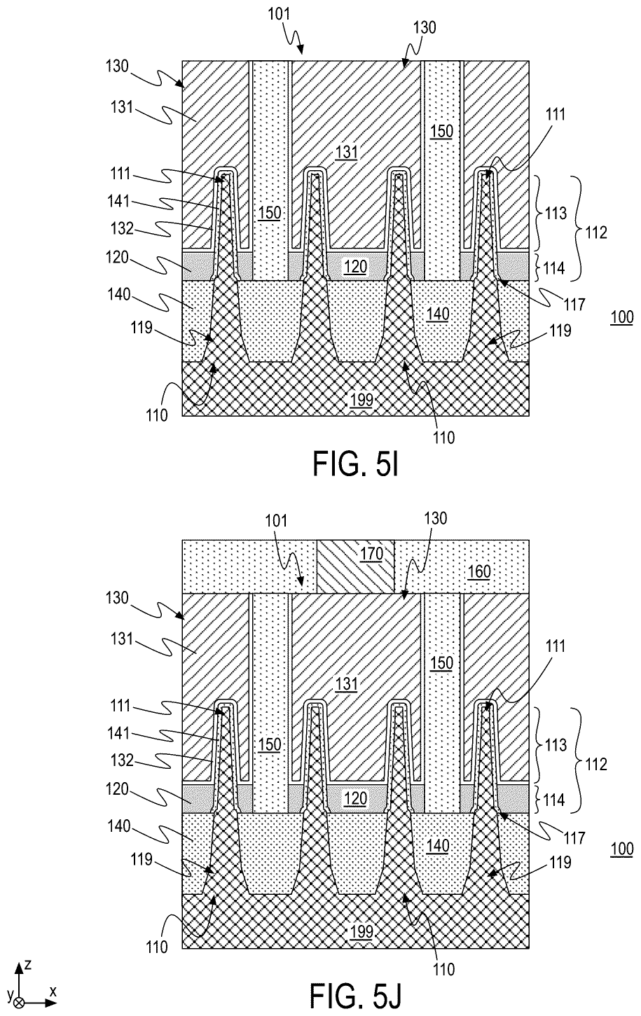

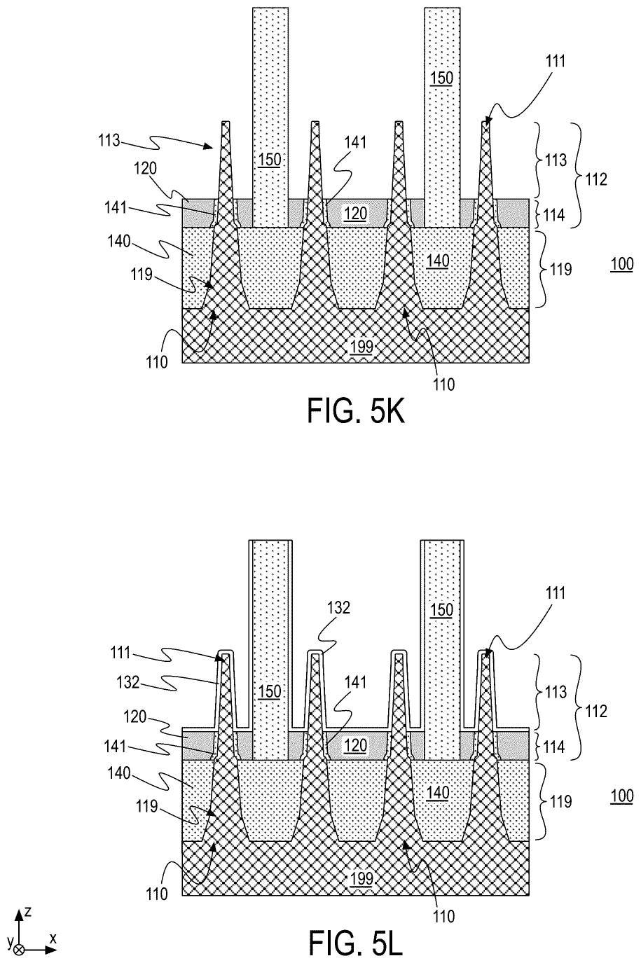

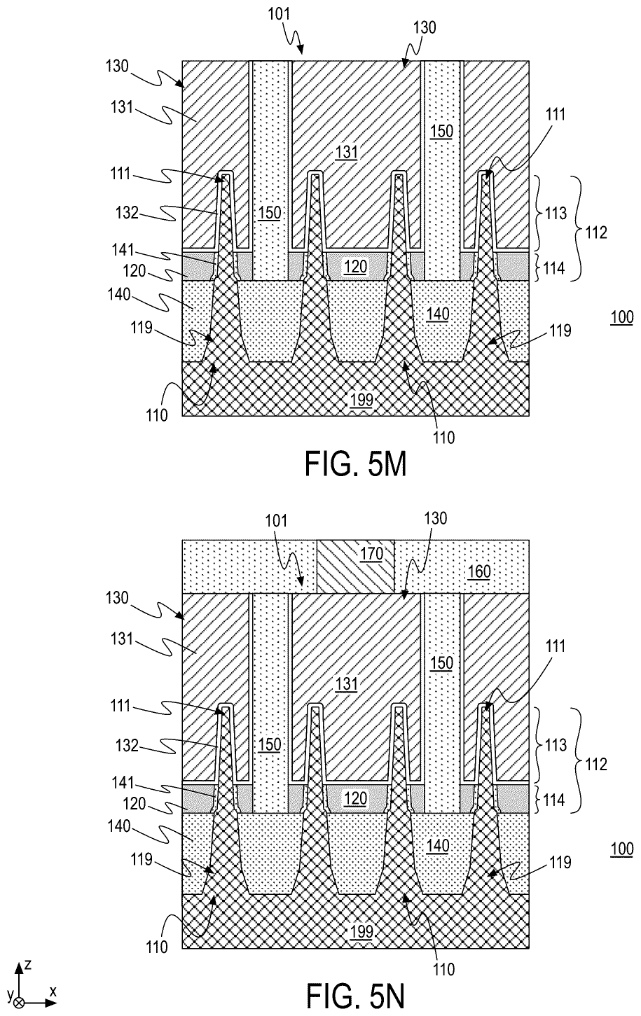

FIGS. 5A, 5B, 5C, 5D, 5E, 5F, 5G, 5H, 5I, 5J, 5K, 5L, 5M, and 5N illustrate cross-sectional profile views of fins 110 and transistors 101, at various stages of manufacture, in accordance with some embodiments.

Returning to FIG. 4, methods 400 begin at operation 410 with receiving a substrate with isolation material over a structure of semiconductor material. The substrate may include any suitable material or materials, for example, as described at least at FIG. 1A. The substrate may be any suitable substrate, such as a wafer, die, etc. One or more fins of semiconductor material may be included in or on the substrate. The fin or fins may be of the same material as the substrate or formed, e.g., deposited, on the substrate. The substrate may also include semiconductor materials, metals, dielectrics, dopants, and other materials commonly found in IC substrates.

An isolation material may be over one or more fins of semiconductor material in or on the substrate. The isolation material may be completely over the fins, e.g., to a level above top portions of the fins, and between adjacent fins (in embodiments having multiple fins). The isolation material may be any sufficiently electrically insulating material, such as a dielectric material. In some embodiments, the isolation material is an oxide. In some such embodiments, the substrate and/or fins are of silicon, and the isolation material includes an oxide of silicon (such as silicon dioxide (SiO₂)).

FIG. 5A shows an example substrate 199 with isolation material 140 over fins 110, e.g., following receipt at operation 410 of methods 400. Substrate 199 may have been received having isolation material 140 over fins 110 of semiconductor material. In many embodiments, fins 110 are of silicon on a silicon substrate 199.

Returning to FIG. 4, methods 400 continue at operation 420 with exposing an upper portion of the fin by removing a first (e.g., upper) portion of the isolation material. The isolation material may be removed by any suitable means. In many embodiments, the isolation material is removed by a selective etch that does not remove (much of) the semiconductor material of the fin(s). Such an etch may remove any isolation material exposed to the etchant, but leave the semiconductor material (mostly) intact. The etch (even if a very selective etch) may remove small amounts of the semiconductor material of the fin. In this way, an upper portion of the fin may be exposed as the isolation material is removed. A base of the fin, below the upper portion, may be left covered. The fin base may be wider than the upper portion of the fin, even before etching away the isolation material, and the isolation material may be above and to both sides of the fin base.

In at least some embodiments, a second (e.g., lower) portion of the isolation material is retained adjacent a base of the fin. In some such embodiments, the fin will have a kink or bulge where the upper portion and the base meet, at an interface with the retained portion of the isolation material. The semiconductor fin may be thinned by the (not perfectly selective) etch of the isolation material, and both the bulge and the still-covered base of the fin may be wider than the upper portion of the fin.

FIG. 5B illustrates upper portions 112 of fins 110 exposed (e.g., following removal of an upper portion of isolation material at operation 420 of methods 400). Isolation material 140 (e.g., a retained, lower portion of isolation material 140) is adjacent base 119 of fin 110, over substrate 199. Base 119 is wider than upper portion 112, and isolation material 140 is above and to both sides of fin bases 119.

Notably, fins 110 have a kink or bulge 117 where upper portion 112 and base 119 meet, at an interface with the retained portion of isolation material 140. Bulge 117 may be an unsuitably wide or otherwise uncontrollable portion of fin 110 and (if used as part of a channel region) may result in unacceptably high leakage currents.

Returning to FIG. 4 and methods 400, a layer of a dielectric material is formed over the exposed upper portion of the fin in some embodiments. In some such embodiments, the layer is formed prior to a subsequent deposition of a dummy gate (or spacer) material. The layer may be formed by any suitable means. For example, the layer may be deposited or thermally grown (e.g., as a native oxide). In some embodiments, the fins are silicon, and the dielectric layer is an oxide of silicon (e.g., SiO₂). In some embodiments, layer of dielectric material is the same material as the retained isolation material, e.g., between the fins and over the substrate. The dielectric layer may advantageously provide protection for the fin (e.g., from etchants or other materials) and may insulate the fin from other adjacent structures (for example, yet to be formed).

FIG. 5C shows layers 141 of dielectric material 140 over upper portions 112 of fins 110. Layers 141 of dielectric material 140 are connected (e.g., directly coupled) near bulges 117 to the regions of dielectric material 140 on both sides of fins 110, adjacent bases 119.

Methods 400 continue at operation 430 by depositing a spacer material over the fin and the retained portion of isolation material. The spacer material may be deposited over selected areas of the fin(s) and isolation material, for example, as a dummy gate. The spacer material may be deposited as a dummy gate following a (e.g., blanket) deposition of a mask material and subsequent removal (e.g., using a photolithographic process) of selected portions of the mask material. The selective removal of portions of mask material may expose portions of fins to be used as channel regions. The retained mask material may be over other portions of semiconductor fins, e.g., to be subsequently covered by source and drain contacts.

The spacer material may be any suitable material and may be deposited by any suitable means. In some embodiments, the spacer material is a conventional dummy gate material, such as polysilicon, deposited by conventional means, but other materials and methods may be employed. Advantageously, the spacer material has an etch selectivity with at least the retained isolation material (e.g., over the substrate and adjacent a fin base). In some embodiments, the spacer material is or includes a nitride or carbide, e.g., of silicon.

FIG. 5D illustrates spacer material 120 over fins 110 (and layers 141 over fin upper portions 112) and the retained portions of isolation material 140 (e.g., following a deposition of spacer material 120 at an operation 430). Spacer material 120 may be over fins 110 in selected openings of a mask material (not shown). For example, mask material may be in front of and behind the viewing plane of FIG. 5D (e.g., in the y direction), as well as to both sides (e.g., in the x direction).

FIG. 5E shows openings 550 in spacer material 120 and between fins 110. Openings 550 may be formed by a dummy gate cut etch, e.g., to separate gates of adjacent structures. Such a gate cut may be by an anisotropic etch, e.g., a dry etch, such as a reactive ion etch (RIE), which may be selective to spacer material 120.

FIG. 5F illustrates isolation spacers 150 separating regions of spacer material 120. Isolation spacers 150 may be electrically insulating materials separating dummy gates of spacer material 120 (e.g., polysilicon or another material).

Methods 400 continue with removing a section (e.g., an upper section) of the spacer material at operation 440. Removing the upper section of spacer material may expose a top portion of the fin. A section (e.g., a lower section) of the spacer material may be retained, for example, level with a middle portion of the fin above the base of the fin (adjacent retained isolation material), but below the exposed top portion of the fin.

In some embodiments, an isotropic and highly selective dry etch is utilized to remove the upper section of spacer material and expose the top portion of the fin (or a layer of a dielectric material over the top portion of the fin). Such an etch may be enabled by the deployment of a proper spacer material, for example, such that there exists an etch selectivity between the spacer material and the layer of dielectric material over the top portion of the fin (or the semiconductor material of the fin, if exposed). For example, a highly selective, isotropic, plasma etch of polysilicon may remove a polysilicon dummy gate and expose a layer of silicon oxide (e.g., SiO₂) dielectric material over a top portion of a silicon fin. In some such embodiments, such a highly selective, dry polysilicon etch is employed and is sufficiently well-controlled to retain a polysilicon spacer adjacent a middle portion of the silicon fin between the base and top portion of the fin. An isotropic and highly selective dry etch may enable a well-controlled region (e.g., of optimal size, shape, and location) of spacer material and a well-controlled deposition of a gate insulator over the spacer material. Such a well-controlled deployment of a gate insulator may advantageously provide consistent and/or optimized control of conduction through channel regions in fins (e.g., due to well-controlled and symmetric deposition of a gate insulator relative to the fins).

FIG. 5G shows a retained section of spacer material 120, level with middle portion 114 of fin 110 above base 119 (e.g., following a removal of some of spacer material 120 at an operation 440). Spacer material 120 provides vertical separation (e.g., along a length or height of fin 110) between top portion 113 of fin 110 and bulge 117 at an interface of materials 120, 140.

Methods 400 continue by forming a gate structure adjacent the top portion of the fin at operation 450. The gate structure may be formed by any suitable means and of any suitable means, for example, by conformally depositing a gate insulator and then filling a gate metal into the volume enclosed by the gate insulator. The gate insulator may be a dielectric material, for example, a layer of a high-K material between the fin (including a channel region, e.g., in the top portion of the fin) and a gate metal. A high-K dielectric material may enable superior electrostatic control of the transistor, for example, relative to only a low-K dielectric material (such as a native oxide passivation layer). In some embodiments, the gate structure is formed by depositing a dielectric material (e.g., a gate insulator) over the top portion of the fin and the spacer material retained adjacent the middle portion of the fin. A high-K dielectric material may be deployed in place of, or in addition to a low-K dielectric material. In some embodiments, the gate dielectric material deposited over the top portion of the fin is deposited over a layer of dielectric material (e.g., a native oxide or passivation layer) already over the top portion of the fin.

In some such embodiments, the gate metal is then formed (e.g., deposited) over the deposited gate dielectric. In some embodiments, the gate metal includes a conformal, liner metal deposited over the gate insulator, and a fill metal formed over (e.g., in the space enclosed by) the liner metal. The gate metal may include a conformally deposited liner metal to act as a contact and/or barrier metal around a fill or bulk metal, which may act as the main conductor and which may be a work-function metal (e.g., to help set a transistor threshold voltage). With the gate structure formed adjacent the top portion of the fin, the middle portion of the fin (and the retained spacer material) may be between (e.g., separating) the gate structure and the base of the fin (adjacent the retained isolation material), as well as the fin bulge at the interface between spacer and isolation materials.

FIG. 5H illustrates gate insulator 132 (e.g., formed by conformal deposition at an operation 450) adjacent top portion 113 of fin 110. Gate insulator 132 is over layer 141 of dielectric material 140. Gate insulator 132 and layer 141 are adjacent top portion 113. Gate insulator 132 and top portion 113 are separated from bulge 117 (and base 119 and regions of isolation material 140) by spacer material 120 and middle portion 114.

FIG. 5I shows device 100 with transistor 101 having gate metal 131 of gate structure 130 (e.g., formed at an operation 450) adjacent channel region 111 and top portion 113 of fin 110. Gate insulator 132 and layer 141 are between channel region 111 and gate metal 131. Gate metal 131 is within conformal gate insulator 132. Gate metal 131 may include multiple metals, e.g., a liner metal conformal to gate insulator 132 and a fill metal. Gate structure 130 (which may include layer 141) is adjacent top portion 113. Gate structure 130, channel region 111, and top portion 113 are separated from bulge 117 (and base 119 and regions of isolation material 140) by spacer material 120 and middle portion 114.

FIG. 5J illustrates device 100 with isolation 160 over transistors 101. Isolation 160 may insulate transistors 101 (e.g., gate structures 130) from structures, e.g., electrical interconnects, in layers above transistors 101. Gate contacts 170 through isolation 160 may electrically couple transistors 101 to electrical interconnects and supply structures in layers above.

FIGS. 5K, 5L, 5M, and 5N illustrate similar structures, but with alternative or additional embodiments. For example, in some embodiments of methods 400, FIG. 5K follows FIG. 5G in a sequence of operations, and FIGS. 5L, 5M, and 5N illustrate embodiments similar to FIGS. 5H, 5I, and 5J.

Returning to FIG. 4 and methods 400, in some embodiments, a top portion of a layer of the dielectric material over the fin (e.g., connected to the regions of the isolation material adjacent the fin base, and between the fin and the regions of spacer material) is removed. For example, in some embodiments, the top portion of the dielectric layer over the top portion of the fin is removed before forming the gate structure. In at least some such embodiments, a portion of the dielectric (e.g., isolation) layer adjacent the middle portion of the fin (e.g., between the spacer material and the middle portion of the fin) is retained. The dielectric layer adjacent the middle portion of the fin may advantageously provide a protective layer over the middle portion of the fin, as well as electrical insulation between the middle portion of the fin and the adjacent spacer material. Removing the top portion of the dielectric layer (e.g., over the top portion of the fin) may enable superior electrostatic control of the transistor, for example, (with a same total dielectric thickness) by the replacement of a low-K dielectric material with a high-K dielectric material.

FIG. 5K shows exposed top portions 113 of fins 110 with layer 141 of dielectric or isolation material between spacer material 120 and middle portion 114 of fin 110, but not over top portions 113 (e.g., following a removal of a top portion of layer 141 before forming a gate structure over spacer material 120 and fin 110).

FIG. 5L illustrates gate insulator 132 (e.g., formed by conformal deposition at an operation 450, similar to the example of FIG. 5H, but following a removal of a top portion of layer 141, as shown in the example of FIG. 5K) adjacent top portion 113 of fin 110. Without layer 141, gate insulator 132 is in contact with top portion 113 of fin 110.

FIG. 5M shows device 100 with transistor 101 having gate metal 131 of gate structure 130 (e.g., formed at an operation 450, similar to the example of FIG. 5I, but after a removal of a top portion of layer 141, as shown in the example of FIG. 5K). Gate metal 131 and gate structure 130 are adjacent channel region 111 and top portion 113 of fin 110. Gate insulator 132 (without layer 141) is all that is between channel region 111 and gate metal 131.

FIG. 5N illustrates device 100 with isolation 160 over transistors 101 (e.g., similar to the example of FIG. 5J, but after a removal of a top portion of layer 141). Isolation 160 may insulate transistors 101 (e.g., gate structures 130) from structures, e.g., electrical interconnects, in layers above transistors 101. Gate contacts 170 through isolation 160 may electrically couple transistors 101 to electrical interconnects and supply structures in layers above.

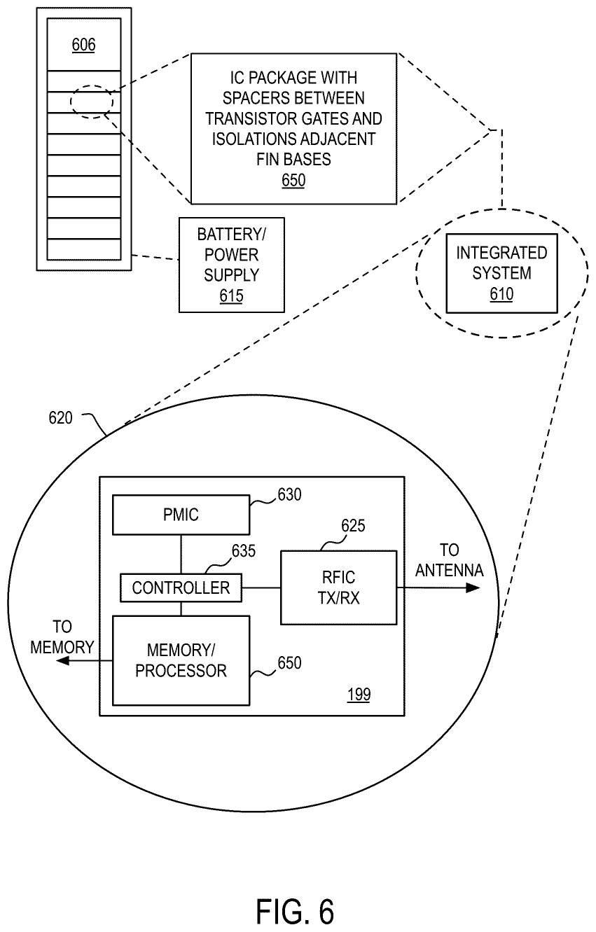

FIG. 6 illustrates a diagram of an example data server machine 606 employing an IC device with FinFETs having spacers between gate structures and isolation materials between fins, in accordance with some embodiments. Server machine 606 may be any commercial server, for example, including any number of high-performance computing platforms disposed within a rack and networked together for electronic data processing, which in the exemplary embodiment includes one or more devices 650 having FinFETs with spacers between gate structures and isolation materials.

Also as shown, server machine 606 includes a battery and/or power supply 615 to provide power to devices 650, and to provide, in some embodiments, power delivery functions such as power regulation. Devices 650 may be deployed as part of a package-level integrated system 610. Integrated system 610 is further illustrated in the expanded view 620. In the exemplary embodiment, devices 650 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 650 is a microprocessor including a static RAM (SRAM) cache memory. As shown, device 650 may be an IC device with FinFETs having spacers between gate structures and isolation materials, as discussed herein. Device 650 may be further coupled to (e.g., communicatively coupled to) a board, an interposer, or a substrate 199 along with, one or more of a power management IC (PMIC) 630, RF (wireless) IC (RFIC) 625 including a wideband RF (wireless) transmitter and/or receiver (TX/RX) (e.g., including a digital baseband and an analog front end module further includes a power amplifier on a transmit path and a low noise amplifier on a receive path), and a controller 635 thereof. In some embodiments, RFIC 625, PMIC 630, controller 635, and device 650 include FinFETs with spacers between gate structures and isolation materials.

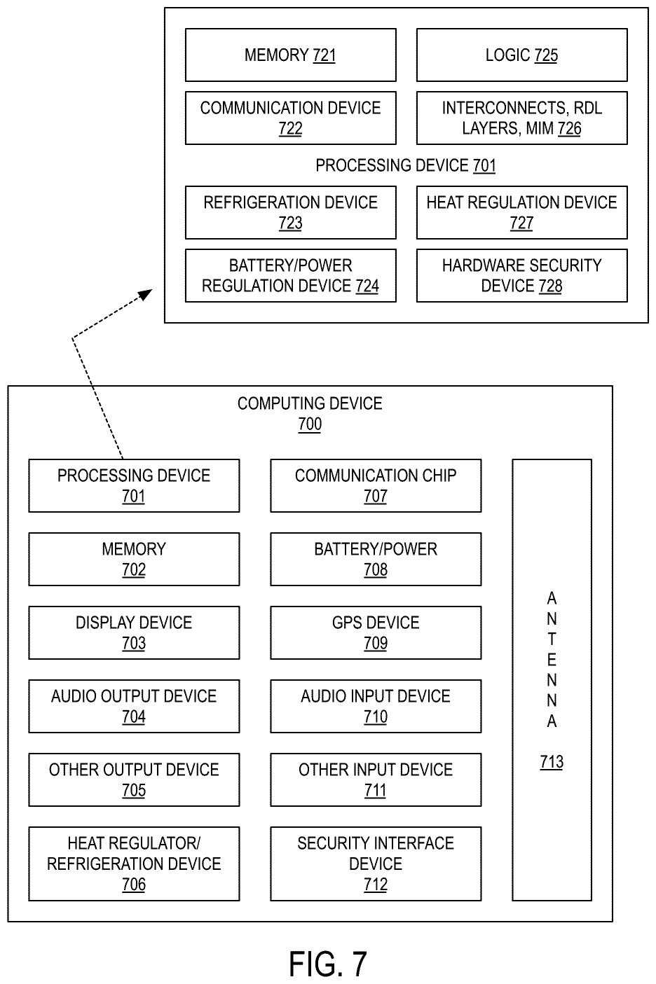

FIG. 7 is a block diagram of an example computing device 700, in accordance with some embodiments. For example, one or more components of computing device 700 may include any of the devices or structures discussed herein. A number of components are illustrated in FIG. 7 as being included in computing device 700, but any one or more of these components may be omitted or duplicated, as suitable for the application. In some embodiments, some or all of the components included in computing device 700 may be attached to one or more printed circuit boards (e.g., a motherboard). In some embodiments, various ones of these components may be fabricated onto a single system-on-a-chip (SoC) die. Additionally, in various embodiments, computing device 700 may not include one or more of the components illustrated in FIG. 7, but computing device 700 may include interface circuitry for coupling to the one or more components. For example, computing device 700 may not include a display device 703, but may include display device interface circuitry (e.g., a connector and driver circuitry) to which display device 703 may be coupled. In another set of examples, computing device 700 may not include an audio output device 704, other output device 705, global positioning system (GPS) device 709, audio input device 710, or other input device 711, but may include audio output device interface circuitry, other output device interface circuitry, GPS device interface circuitry, audio input device interface circuitry, audio input device interface circuitry, to which audio output device 704, other output device 705, GPS device 709, audio input device 710, or other input device 711 may be coupled.

Computing device 700 may include a processing device 701 (e.g., one or more processing devices). As used herein, the term “processing device” or “processor” indicates a device that processes electronic data from registers and/or memory to transform that electronic data into other electronic data that may be stored in registers and/or memory. Processing device 701 may include a memory 721, a communication device 722, a refrigeration device 723, a battery/power regulation device 724, logic 725, interconnects 726 (i.e., optionally including redistribution layers (RDL) or metal-insulator-metal (MIM) devices), a heat regulation device 727, and a hardware security device 728.

Processing device 701 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 700 may include a memory 702, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 702 includes memory that shares a die with processing device 701. This memory may be used as cache memory and may include embedded dynamic random-access memory (eDRAM) or spin transfer torque magnetic random-access memory (STT-MRAM).

Computing device 700 may include a heat regulation/refrigeration device 706. Heat regulation/refrigeration device 706 may maintain processing device 701 (and/or other components of computing device 700) at a predetermined low temperature during operation.

In some embodiments, computing device 700 may include a communication chip 707 (e.g., one or more communication chips). For example, the communication chip 707 may be configured for managing wireless communications for the transfer of data to and from computing device 700. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 707 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 707 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 707 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 707 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 707 may operate in accordance with other wireless protocols in other embodiments. Computing device 700 may include an antenna 713 to facilitate wireless communications and/or to receive other wireless communications (such as AM or FM radio transmissions).

In some embodiments, communication chip 707 may manage wired communications, such as electrical, optical, or any other suitable communication protocols (e.g., the Ethernet). As noted above, communication chip 707 may include multiple communication chips. For instance, a first communication chip 707 may be dedicated to shorter-range wireless communications such as Wi-Fi or Bluetooth, and a second communication chip 707 may be dedicated to longer-range wireless communications such as GPS, EDGE, GPRS, CDMA, WiMAX, LTE, EV-DO, or others. In some embodiments, a first communication chip 707 may be dedicated to wireless communications, and a second communication chip 707 may be dedicated to wired communications.

Computing device 700 may include battery/power circuitry 708. Battery/power circuitry 708 may include one or more energy storage devices (e.g., batteries or capacitors) and/or circuitry for coupling components of computing device 700 to an energy source separate from computing device 700 (e.g., AC line power).

Computing device 700 may include a display device 703 (or corresponding interface circuitry, as discussed above). Display device 703 may include any visual indicators, such as a heads-up display, a computer monitor, a projector, a touchscreen display, a liquid crystal display (LCD), a light-emitting diode display, or a flat panel display, for example.

Computing device 700 may include an audio output device 704 (or corresponding interface circuitry, as discussed above). Audio output device 704 may include any device that generates an audible indicator, such as speakers, headsets, or earbuds, for example.

Computing device 700 may include an audio input device 710 (or corresponding interface circuitry, as discussed above). Audio input device 710 may include any device that generates a signal representative of a sound, such as microphones, microphone arrays, or digital instruments (e.g., instruments having a musical instrument digital interface (MIDI) output).

Computing device 700 may include a GPS device 709 (or corresponding interface circuitry, as discussed above). GPS device 709 may be in communication with a satellite-based system and may receive a location of computing device 700, as known in the art.

Computing device 700 may include other output device 705 (or corresponding interface circuitry, as discussed above). Examples of the other output device 705 may include an audio codec, a video codec, a printer, a wired or wireless transmitter for providing information to other devices, or an additional storage device.

Computing device 700 may include other input device 711 (or corresponding interface circuitry, as discussed above). Examples of the other input device 711 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 700 may include a security interface device 712. Security interface device 712 may include any device that provides security measures for computing device 700 such as intrusion detection, biometric validation, security encode or decode, access list management, malware detection, or spyware detection.

Computing device 700, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-7. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a fin of semiconductor material, the fin including a base of the fin under a channel region, a dielectric material adjacent the base of the fin, the dielectric material including oxygen, a gate structure over the fin and adjacent the channel region, the gate structure including a gate metal and a gate insulator, and an intervening material adjacent the fin and over the dielectric material, wherein a first portion of the gate insulator is between the gate metal and the channel region and a second portion of the gate insulator is between the gate metal and the intervening material.

In one or more second embodiments, further to the first embodiments, the fin is a first fin, and also including a second fin, wherein the intervening and dielectric materials are between the first and second fins, the gate structure is over the first and second fins, the first portion of the gate insulator is between the gate metal and the first fin, the second portion of the gate insulator is between the first and second fins, and a third portion of the gate insulator is between the gate metal and the second fin.

In one or more third embodiments, further to the first or second embodiments, the first portion connects to the second portion at a first height, and the third portion connects to the second portion at a second height substantially equal to the first height.

In one or more fourth embodiments, further to the first through third embodiments, the dielectric material adjacent the base of the fin is a first section of the dielectric material, the intervening material adjacent the fin and over the dielectric material is a first region of the intervening material, and also including a second section of the dielectric material and a second region of the intervening material, wherein the fin is between the first and second sections of the dielectric material, the fin is between the first and second regions of the intervening material, the gate structure is over the first and second regions of the intervening material, and a third portion of the gate insulator is between the gate metal and the second region of the intervening material.

In one or more fifth embodiments, further to the first through fourth embodiments, the apparatus also includes a layer of the dielectric material between the first or second region of the intervening material and a middle portion of the fin, wherein a top portion of the fin is adjacent the gate structure, the middle portion of the fin is between the base of the fin and the top portion of the fin, and the layer of the dielectric material is connected to the first or second section of the dielectric material adjacent the base of the fin.

In one or more sixth embodiments, further to the first through fifth embodiments, the layer of the dielectric material is over the fin, between the channel region and the first portion of the gate insulator, and coupled to the first and second sections of the dielectric material.

In one or more seventh embodiments, further to the first through sixth embodiments, the second portion of the gate insulator is at a third height along the fin, the third portion of the gate insulator is at a fourth height along the fin, and the third height is substantially equal to the fourth height.

In one or more eighth embodiments, further to the first through seventh embodiments, a first width of the fin is at a first interface between the second portion of the gate insulator and the intervening material, a second width of the fin is at a second interface between the dielectric material and the intervening material, and the second width is more than 20% greater than the first width.

In one or more ninth embodiments, further to the first through eighth embodiments, a middle portion of the fin is adjacent the intervening material, and between the base of the fin and a top portion of the fin adjacent the gate structure, and a first height of the intervening material along the middle portion of the fin is equal to or less than half of a second height of the fin.

In one or more tenth embodiments, further to the first through ninth embodiments, the fin includes silicon, the intervening material includes silicon, and the dielectric material includes silicon.

In one or more eleventh embodiments, an apparatus includes a fin between first and second regions of a spacer material, the fin including a base of the fin under a channel region, third and fourth regions of an isolation material, wherein the first region is over the third region, and the second region is over the fourth region, a gate metal over the channel region and the first and second regions, and a dielectric material between the channel region and the gate metal, wherein the dielectric material is between the gate metal and the first region and between the gate metal and the second region.

In one or more twelfth embodiments, further to the eleventh embodiments, a first layer of the isolation material is between the fin and the first region, and a second layer of the isolation material is between the fin and the second region.

In one or more thirteenth embodiments, further to the eleventh or twelfth embodiments, the first and second layers are between the fin and the dielectric material.

In one or more fourteenth embodiments, further to the eleventh through thirteenth embodiments, a first portion of the dielectric material between the gate metal and the first region is at a first height, and a second portion of the dielectric material between the gate metal and the second region is at a second height substantially equal to the first height.

In one or more fifteenth embodiments, further to the eleventh through fourteenth embodiments, the fin includes silicon, the spacer material includes silicon, and the isolation material includes silicon.

In one or more sixteenth embodiments, a method includes receiving a substrate including an isolation material over a fin of semiconductor material, exposing an upper portion of the fin by removing a first portion of the isolation material, wherein a second portion of the isolation material is retained adjacent a base of the fin, depositing a spacer material over the fin and the second portion of the isolation material, removing a first section of the spacer material, wherein a second section of the spacer material is retained level with a middle portion of the fin above the base, the middle portion below a top portion of the fin, the upper portion including the middle and top portions, and forming a gate structure adjacent the top portion of the fin, wherein the middle portion is between the gate structure and the base.

In one or more seventeenth embodiments, further to the sixteenth embodiments, the method also includes forming a layer of a dielectric material over the exposed upper portion of the fin before depositing the spacer material.

In one or more eighteenth embodiments, further to the sixteenth or seventeenth embodiments, the method also includes removing a top portion of the layer of the dielectric material before forming the gate structure, wherein the top portion of the layer is over the top portion of the fin, and a middle portion of the layer is retained adjacent the middle portion of the fin.

In one or more nineteenth embodiments, further to the sixteenth through eighteenth embodiments, forming the gate structure includes depositing a dielectric material over the top portion of the fin and the retained second section of the spacer material.

In one or more twentieth embodiments, further to the sixteenth through nineteenth embodiments, removing the first section of the spacer material includes a selective isotropic dry etch that exposes the top portion of the fin or a layer of a dielectric material over the top portion.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a fin of semiconductor material, the fin comprising a base of the fin under a channel region;
a dielectric material adjacent the base of the fin, the dielectric material comprising oxygen;
a gate structure over the fin and adjacent the channel region, the gate structure comprising a gate metal and a gate insulator; and
an intervening material adjacent the fin and over the dielectric material, wherein a first portion of the gate insulator is between the gate metal and the channel region and a second portion of the gate insulator is between the gate metal and the intervening material.

2. The apparatus of claim 1, wherein the fin is a first fin, and further comprising a second fin, wherein the intervening and dielectric materials are between the first and second fins, the gate structure is over the first and second fins, the first portion of the gate insulator is between the gate metal and the first fin, the second portion of the gate insulator is between the first and second fins, and a third portion of the gate insulator is between the gate metal and the second fin.

3. The apparatus of claim 2, wherein the first portion connects to the second portion at a first height, and the third portion connects to the second portion at a second height substantially equal to the first height.

4. The apparatus of claim 1, wherein the dielectric material adjacent the base of the fin is a first section of the dielectric material, the intervening material adjacent the fin and over the dielectric material is a first region of the intervening material, and further comprising a second section of the dielectric material and a second region of the intervening material, wherein:
the fin is between the first and second sections of the dielectric material;
the fin is between the first and second regions of the intervening material;
the gate structure is over the first and second regions of the intervening material; and
a third portion of the gate insulator is between the gate metal and the second region of the intervening material.

5. The apparatus of claim 4, further comprising a layer of the dielectric material between the first or second region of the intervening material and a middle portion of the fin, wherein a top portion of the fin is adjacent the gate structure, the middle portion of the fin is between the base of the fin and the top portion of the fin, and the layer of the dielectric material is connected to the first or second section of the dielectric material adjacent the base of the fin.

6. The apparatus of claim 5, wherein the layer of the dielectric material is over the fin, between the channel region and the first portion of the gate insulator, and coupled to the first and second sections of the dielectric material.

7. The apparatus of claim 4, wherein:
the second portion of the gate insulator is at a third height along the fin;
the third portion of the gate insulator is at a fourth height along the fin; and
the third height is substantially equal to the fourth height.

8. The apparatus of claim 1, wherein:
a first width of the fin is at a first interface between the second portion of the gate insulator and the intervening material;
a second width of the fin is at a second interface between the dielectric material and the intervening material; and
the second width is more than 20% greater than the first width.

9. The apparatus of claim 1, wherein a middle portion of the fin is adjacent the intervening material, and between the base of the fin and a top portion of the fin adjacent the gate structure, and a first height of the intervening material along the middle portion of the fin is equal to or less than half of a second height of the fin.

10. The apparatus of claim 1, wherein the fin comprises silicon, the intervening material comprises silicon, and the dielectric material comprises silicon.

11. An apparatus, comprising:
a fin between first and second regions of a spacer material, the fin comprising a base of the fin under a channel region;
third and fourth regions of an isolation material, wherein the first region is over the third region, and the second region is over the fourth region;
a gate metal over the channel region and the first and second regions; and
a dielectric material between the channel region and the gate metal, wherein the dielectric material is between the gate metal and the first region and between the gate metal and the second region.

12. The apparatus of claim 11, wherein a first layer of the isolation material is between the fin and the first region, and a second layer of the isolation material is between the fin and the second region.

13. The apparatus of claim 12, wherein the first and second layers are between the fin and the dielectric material.

14. The apparatus of claim 13, wherein a first portion of the dielectric material between the gate metal and the first region is at a first height, and a second portion of the dielectric material between the gate metal and the second region is at a second height substantially equal to the first height.

15. The apparatus of claim 14, wherein the fin comprises silicon, the spacer material comprises silicon, and the isolation material comprises silicon.

16. A method, comprising:
receiving a substrate comprising an isolation material over a fin of semiconductor material;
exposing an upper portion of the fin by removing a first portion of the isolation material, wherein a second portion of the isolation material is retained adjacent a base of the fin;
depositing a spacer material over the fin and the second portion of the isolation material;
removing a first section of the spacer material, wherein a second section of the spacer material is retained level with a middle portion of the fin above the base, the middle portion below a top portion of the fin, the upper portion comprising the middle and top portions; and
forming a gate structure adjacent the top portion of the fin, wherein the middle portion is between the gate structure and the base.

17. The method of claim 16, further comprising forming a layer of a dielectric material over the exposed upper portion of the fin before depositing the spacer material.

18. The method of claim 17, further comprising removing a top portion of the layer of the dielectric material before forming the gate structure, wherein the top portion of the layer is over the top portion of the fin, and a middle portion of the layer is retained adjacent the middle portion of the fin.

19. The method of claim 16, wherein forming the gate structure comprises depositing a dielectric material over the top portion of the fin and the retained second section of the spacer material.

20. The method of claim 16, wherein removing the first section of the spacer material comprises a selective isotropic dry etch that exposes the top portion of the fin or a layer of a dielectric material over the top portion.
